(19) United States
(12) Patent Application Publication
(10) Pub. No.: US 2022/0375883 A1
(43) Pub. Date: Nov. 24, 2022

(54) Method for Fabricating an Electrical Device Package Comprising Plateable Encapsulating Layers

(71) Applicant: Infineon Technologies AG, Neubiberg (DE)

(72) Inventors: Kok Yau Chua, Melaka (MY); Paul Armand Asentista Calo, Villach (AT); Chee Hong Lee, Melaka (MY)

(21) Appl. No.: 17/741,597

(22) Filed: May 11, 2022

(30) Foreign Application Priority Data
May 14, 2021 (DE) 102021112577.4

(51) Int. Cl. H01L 23/64; H01L 49/02; H01L 23/498; H01L 21/56; H01L 21/48

(52) U.S. Cl. CPC H01L 23/647; H01L 28/10; H01L 28/20; H01L 28/60; H01L 23/49861; H01L 23/49838; H01L 21/565; H01L 21/4839

(57) ABSTRACT

A method for fabricating an electrical or electronic device package includes providing a first plateable encapsulation layer; activating first selective areas on a main surface of the first plateable encapsulation layer; forming a first metallization layer by electrolytic or electroless plating on the first activated areas; and fabricating a passive electrical component on the basis of the first metallization layer.

### TECHNICAL FIELD

The present disclosure is related to a method for fabricating an electrical device package and to an electrical device package.

### BACKGROUND

Nowadays electrical device packages, in particular semiconductor device packages, very often require additional passive components like, for example, inductors, capacitors, or resistors for performing functions like signal filtering, decoupling, or noise suppression, etc. These passive components are normally installed on the customer board (PCB) where they occupy a relatively large area due to their dimension and pick/place bonding accuracy. A further problem is that the spatial distances between the passive components and the functional semiconductor chips are far resulting in losses, low efficiency, and limitation in compactness of the final product.

Only as an example, a half-bridge circuit essentially contains discrete semiconductor device packages containing two semiconductor switching chips, a gate driver chip for controlling the semiconductor switching chips, an output inductor and an output capacitor for delivering the output voltage. The discrete semiconductor device packages, the output inductor and the output capacitor are usually mounted on a printed circuit board resulting in the problems as discussed above.

For these and other reasons there is a need for the present disclosure.

### SUMMARY

A first aspect of the present disclosure is related to a method for fabricating an electrical device package, the method comprising providing a first plateable encapsulation layer, activating first selective areas on a main surface of the first plateable encapsulation layer, forming a first metallization layer by electrolytic or electroless plating on the first activated, and fabricating a passive electrical component on the basis of the first metallization layer.

A second aspect of the present disclosure is related to an electrical device package comprising a first plateable encapsulation layer comprising first activated areas on a main surface of the first plateable encapsulation layer, a first metallization layer disposed on the first activated areas; and a passive electrical component formed on the basis of the first metallization layer.

A third aspect of the present disclosure is related to a method for fabricating an electrical device package, the method comprising providing a first encapsulation layer, forming a first metallization layer by electrolytic or electroless plating on the first encapsulation layer, applying a second encapsulation layer onto the first metallization layer, forming a second metallization layer by electrolytic or electroless plating on the second encapsulation layer, and fabricating a passive electrical component on the basis of the first and second metallization layers.

A forth aspect of the present disclosure is related to an electrical device package comprising a first encapsulation layer, a first metallization layer disposed on the first encapsulation layer, a second encapsulation layer disposed on the first metallization layer, a second metallization layer disposed on the second encapsulation layer, and a passive electrical device fabricated on the basis of first and second metallization layers.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description.

The elements of the drawings are not necessarily to scale relative to each other. Like reference numerals designate corresponding similar parts.

FIG. 1 shows a flow diagram of a method for fabricating an electrical or electronic device package according to an example.

FIG. 2 comprises FIG. 2A to 2J and shows schematic perspective representations for illustrating a method for fabricating an electrical or electronic device package according to an example in which as a passive component a capacitor is manufactured.

FIG. 3 comprises FIG. 3A to 3C and shows a perspective view of an intermediate product of the process flow of FIG. 2A-2J (A), a vertical cross-section through the intermediate product (B), and a sketch illustrating the well-known formula for the capacitance of a capacitor.

FIG. 4 comprises FIG. 4A to 4I and shows schematic perspective representations for illustrating a method for fabricating an electrical or electronic device package according to an example in which as a passive component an inductor is manufactured (A, B, C, D, E, F, G, and I), with FIG. 4H illustrating a close-up view of metallization areas from FIG. 4G.

FIG. 5 comprises FIG. 5A to 5C and shows a perspective view of a section of an intermediate product of a process flow of FIG. 4A-4I (A), a vertical cross-section through the intermediate product (B), and a sketch illustrating the well-known formula for the inductance of an inductor.

FIG. 6 comprises FIG. 6A to 6C and shows a perspective view of an intermediate product of a process flow of the fabrication of an electrical or electronic device in which as a passive component a resistor is manufactured (A), an enlarged section of this intermediate product, and a diagram showing the achievable resistance values in dependence on the used metal type together with the well-known formula for the resistance of the resistor.

FIG. 7 comprises FIGS. 7A and 7B and shows a perspective view of an intermediate product of a process flow of the fabrication of an electrical or electronic device in which as a passive component a transformer is manufactured (A), and a vertical cross-section through the intermediate product (B)

FIG. 8 comprises FIGS. 8A and 8B and shows a perspective view of an electrical or electronic device in which as a passive component an inductor is manufactured (A), and another perspective view of the device also showing the underlying semiconductor device structure.

FIG. 9 comprises FIG. 9A to 9C and illustrates a method of fabricating an inductor as well as a capacitor in one device package by showing two perspective views of two different intermediate products each comprising an inductor (A, B), and a process flow similar to the one shown in FIG. 2A to 2J for fabricating a capacitor on top of the inductor.

### DETAILED DESCRIPTION

In the following detailed description, reference is made to the accompanying drawings, which form a part hereof, and in which is shown by way of illustration specific embodiments in which the disclosure may be practiced. In this regard, directional terminology, such as “top”, “bottom”, “front”, “back”, “leading”, “trailing”, etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present disclosure. The following detailed description, therefore, is not to be taken in a limiting sense, and the scope of the present disclosure is defined by the appended claims.

It is to be understood that the features of the various exemplary embodiments described herein may be combined with each other, unless specifically noted otherwise.

As employed in this specification, the terms “bonded”, “attached”, “connected”, “coupled” and/or “electrically connected/electrically coupled” are not meant to mean that the elements or layers must directly be contacted together; intervening elements or layers may be provided between the “bonded”, “attached”, “connected”, “coupled” and/or “electrically connected/electrically coupled” elements, respectively. However, in accordance with the disclosure, the above-mentioned terms may, optionally, also have the specific meaning that the elements or layers are directly contacted together, i.e. that no intervening elements or layers are provided between the “bonded”, “attached”, “connected”, “coupled” and/or “electrically connected/electrically coupled” elements, respectively.

Further, the word “over” used with regard to a part, element or material layer formed or located “over” a surface may be used herein to mean that the part, element or material layer be located (e.g. placed, formed, deposited, etc.) “indirectly on” the implied surface with one or more additional parts, elements or layers being arranged between the implied surface and the part, element or material layer. However, the word “over” used with regard to a part, element or material layer formed or located “over” a surface may, optionally, also have the specific meaning that the part, element or material layer be located (e.g. placed, formed, deposited, etc.) “directly on”, e.g. in direct contact with, the implied surface.

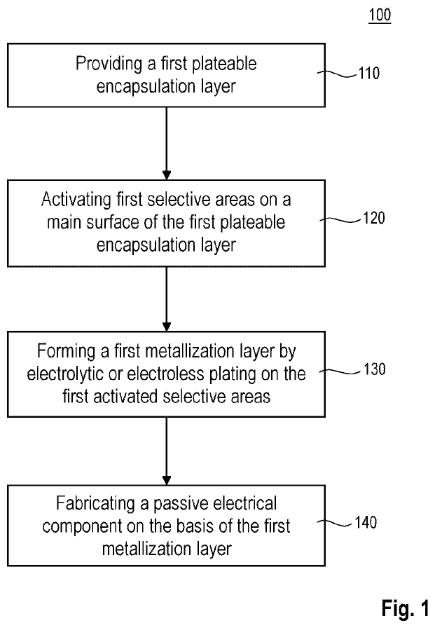

FIG. 1 shows a flow diagram of a method for fabricating an electrical or electronic device package according to an example.

The method 100 according to FIG. 1 comprises providing a first plateable encapsulation layer (110), activating first selective areas on a main surface of the first plateable encapsulation layer (120), forming a first metallization layer by electrolytic or electroless plating on the first activated selective areas (130), and fabricating a passive electrical component on the basis of the first metallization layer (140).

According to an embodiment of the method 100, the first plateable encapsulation layer can be provided in such a way that a substrate is provided and the first plateable encapsulation layer is disposed on the substrate. The substrate can be any usual and conventional substrate like a leadframe, a direct copper bond (DCB), an active metal braze (AMB), an insulated metal substrate (IMS), or a printed metal board (PCB). However, it can be even more than that, in particular anything which allows the first plateable encapsulation layer to be formed on it or surround it.

The first and possible further plateable encapsulation layers may comprise a laser-activatable material as, for example, an additive like a laser direct structuring (LDS) additive, embedded in an encapsulant host material, and sweeping the laser beam over the selected regions results in activating the laser-activatable material. According to an example thereof, the additive is selected from the group consisting of any kinds of metal insulated with powder (in nano size), copper chromium oxide (spinel), copper hydroxide phosphate, copper phosphate, copper chromium oxide spinel, a copper sulfate, a cuprous thiocyanate, an organic metal complex, a palladium/palladium-containing heavy metal complex, a metal oxide, a metal oxide-coated filler, antimony doped tin oxide coated on mica, a copper containing metal oxide, a zinc containing metal oxide, a tin containing metal oxide, a magnesium containing metal oxide, an aluminum containing metal oxide, a gold containing metal oxide, a silver containing metal oxide, and a combination thereof.

The present disclosure offers significant advantages over the prior art solutions. In particular, it provides a flexible concept to form electrical passive components by means of plateable encapsulants. The fabrication method allows mask-less laser patterning together with metal plating which can be done in a batch process. It is, however, also possible to perform mask-based patterning by, for example, use a (metallic) mask to cover part of the layer so that a laser beam can sweep over and only activate the uncovered areas. The passive components can be integrated with scalability in a stacking manner while maintain the lateral (x & y) package dimensions. Hence the present disclosure offers a flexible and customizable interconnection architecture.

According to an embodiment of the method 100, the passive electrical component is a capacitor comprising a first capacitor plate fabricated in the first metallization layer and at least one second capacitor plate fabricated in the second metallization layer.

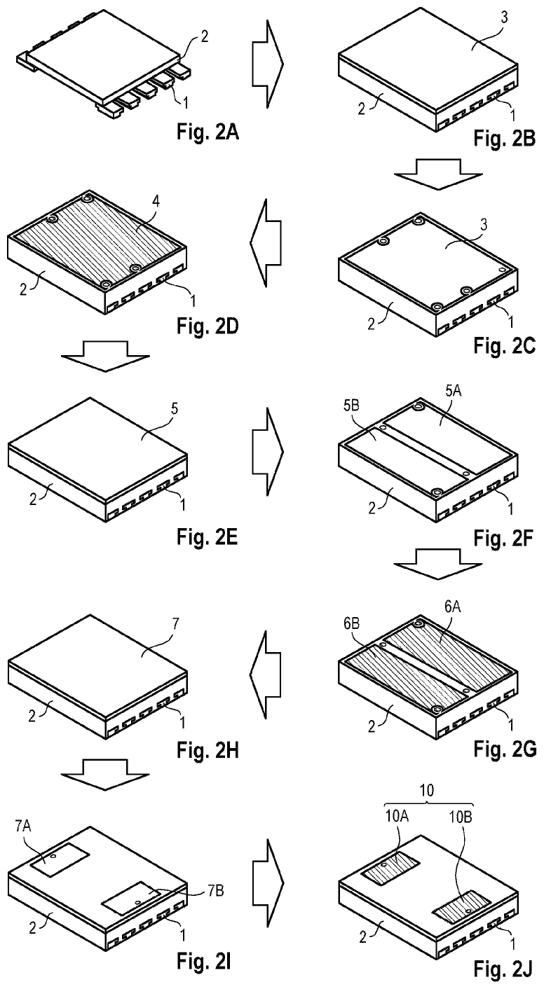

FIG. 2 comprises FIG. 2A to 2J and illustrates a method for fabricating an electrical or electronic device package in which a capacitor is manufactured as a passive component.

FIG. 2A shows the initial constellation given by an assembly comprising a leadframe or any other substrate 1 and any kind of structure 2 disposed on the substrate 1. The structure 2 can, for example, be a semiconductor chip package comprising one or more semiconductor chips interconnected to form an electronic circuit like, for example, a half-bridge circuit.

FIG. 2B shows the assembly after depositing a first plateable encapsulation layer 3 onto the structure 2. The first plateable encapsulation layer 3 can be deposited so that it covers the upper main face as well as parts of the side faces of the structure 2.

FIG. 2C shows the assembly after activating the upper main surface of the first plateable encapsulation layer 3 and thereby forming electrically conductive areas on the upper main surface of the first plateable encapsulation layer 3. The activation can be done by a laser beam sweeping over the upper surface of the first plateable encapsulation layer 3. In the present case essentially the complete area without a narrow edge portion of the upper main surface of the first plateable encapsulation layer 3 is activated by the laser beam.

FIG. 2D shows the assembly after forming a first metallization layer 4 by electrolytic or electroless plating on the electrically conductive area. The first metallization layer 4 will turn out to become the lower plate of the two capacitors to be formed.

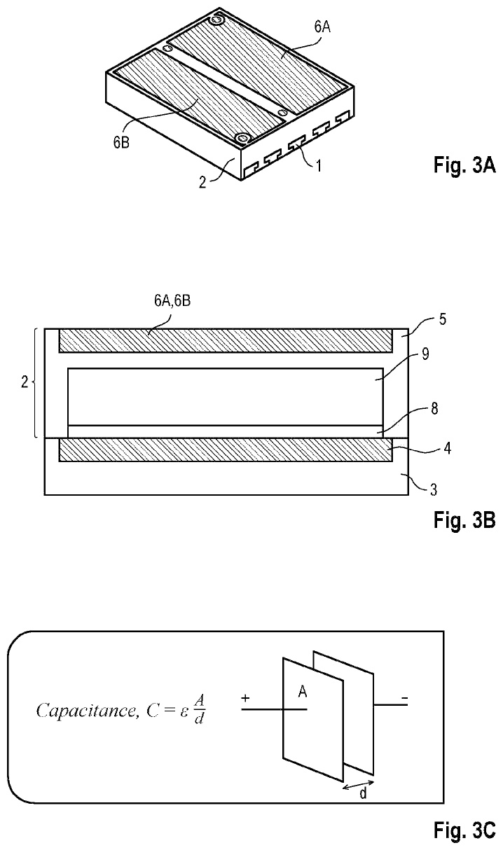

FIG. 2E shows the assembly after depositing a second plateable encapsulation layer 5 onto the upper main face of the first metallization layer 4. Before depositing the second plateable encapsulation layer 5, an adhesion layer could be deposited on the upper main face of the first metallization layer 4 followed by a layer of a high dielectric material in order to increase the capacitance of the capacitor (see FIG. 3B).

FIG. 2F shows the assembly after activating areas of the upper main surface of the second plateable encapsulation layer 5 and thereby forming electrically conductive areas on the upper main surface of the first plateable encapsulation layer 5. The activation can be done by a laser beam sweeping over the upper surface of the second plateable encapsulation layer 5. In the present case two areas 5A and 5B are activated by the laser beam, the areas 5A and 5B lying in a side-by-side spatial relationship. Only a narrow strip separating the areas 5A and 5B and a narrow edge portion of the upper main surface of the first plateable encapsulation layer 5 are not activated by the laser beam.

FIG. 2G shows the assembly after forming a second metallization layer 6 comprising metallization layer areas 6A and 6B by electrolytic or electroless plating on the electrically conductive areas 5A and 5B. The metallization layers 6A and 6B will turn out to become the upper plates of the two capacitors to be formed. It is practical that each one of the two capacitors has a capacitance of 2.22 pF.

FIG. 2H shows the assembly after depositing a third plateable encapsulation layer 7 onto the upper main face of the second metallization layer areas 6A and 6B.

FIG. 2I shows the assembly after activating areas of the upper main surface of the third plateable encapsulation layer 7 and thereby forming electrically conductive areas 7A and 7B on the upper main surface of the first plateable encapsulation layer 7. The activation can be done by a laser beam sweeping over the upper surface of the third plateable encapsulation layer 7. In the present case two areas 7A and 7B are activated by the laser beam, the areas 7A and 7B lying in an opposing spatial relationship.

FIG. 2J shows the assembly after forming a third metallization layer 10 comprising metallization layer areas 10A and 10B by electrolytic or electroless plating on the electrically conductive areas 7A and 7B. The metallization layers 10A and 10B will serve as external terminals of the finished device package.

FIG. 3 comprises FIGS. 3A and 3B and shows further details of the intermediate product as was shown in FIG. 2G.

FIG. 3A corresponds to FIG. 2G and shows again the assembly after forming a second metallization layer 6 comprising metallization layer areas 6A and 6B.

FIG. 3B shows a vertical cross-section through the intermediate product. As was indicated above, before depositing the second plateable encapsulation layer 5 a nonconductive adhesive layer 8 can be deposited on the upper main surface of the first metallization layer 4 and thereafter a high dielectric material layer 9 can be attached to the adhesive layer 8.

FIG. 3C shows a sketch illustrating the well-known formula for the capacitance of a capacitor with ε being the permittivity of the dielectric material, A the area of the plates, and d the distance between the plates.

According to a further embodiment of the method 100, the passive electrical component is an inductor.

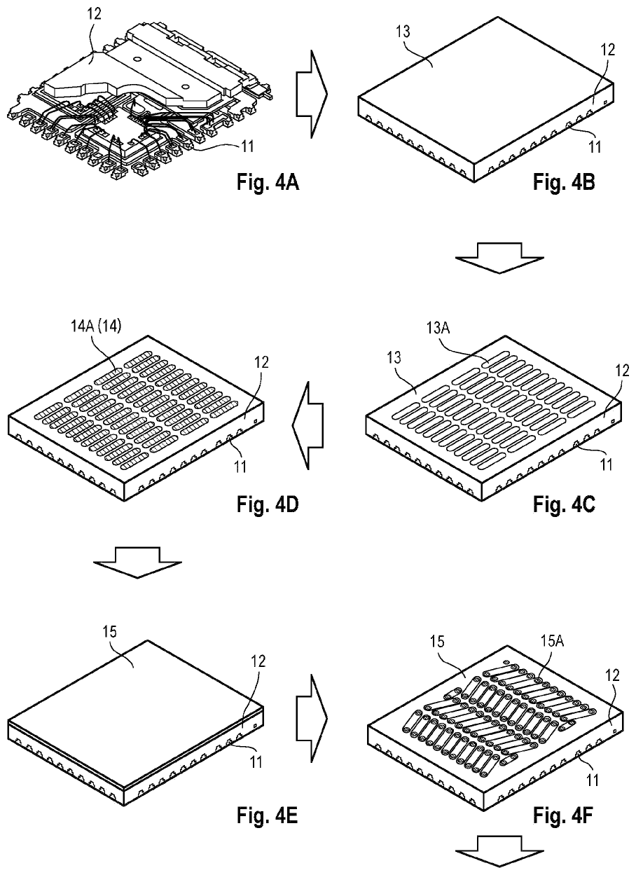

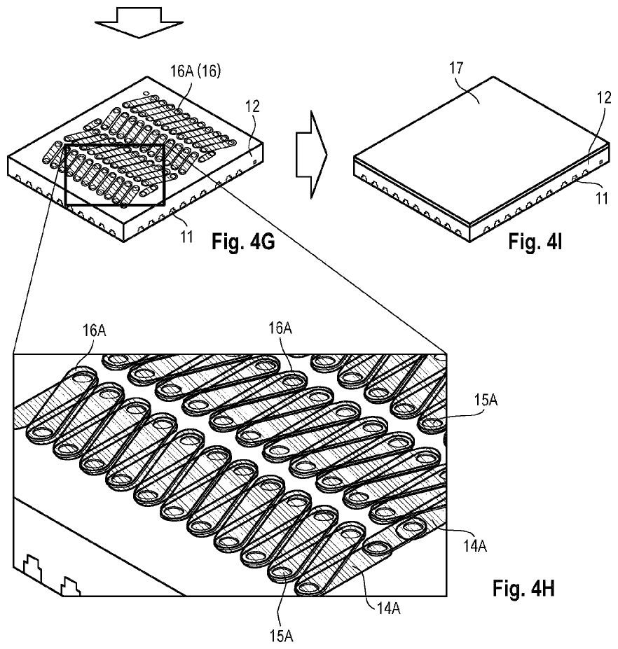

FIG. 4 comprises FIG. 4A to 4I and illustrates a method for fabricating an electrical or electronic device package in which an inductor is manufactured as a passive component.

FIG. 4A shows the initial constellation given by an assembly comprising a leadframe or any other substrate 11 and any kind of structure 12 disposed on the substrate 11. The structure 12 can, for example, be a semiconductor chip package comprising one or more semiconductor chips interconnected to form an electronic circuit like, for example, a half-bridge circuit.

FIG. 4B shows the assembly after depositing a first plateable encapsulation layer 13 onto the structure 12. The first plateable encapsulation layer 13 can be deposited so that it covers the upper main face as well as parts of the side faces of the structure 12.

FIG. 4C shows the assembly after activating areas 13A of the upper main surface of the first plateable encapsulation layer 13 and thereby forming activated areas 13A on the upper main surface of the first plateable encapsulation layer 3. The activation can be done by a laser beam sweeping over the upper surface of the first plateable encapsulation layer 3. In the present case a plurality of strip-like areas will be activated which can be seen in FIG. 4D.

FIG. 4D shows the assembly after forming a first metallization layer 14 in the form of strip-like metallization areas 14A by electrolytic or electroless plating on the electrically conductive areas. The metallization areas 14A will turn out to become first lower portions of windings of the inductor to be formed. As can be seen in FIGS. 4C and D, the activated areas 13A and the strip-like metallization areas 14A can be arranged in four rows, the rows lying next to each other wherein in each row the strips are arranged in parallel and side-by-side with each other. Consequently all strip-like metallization layers 14A extend in one and the same longitudinal direction of the strips.

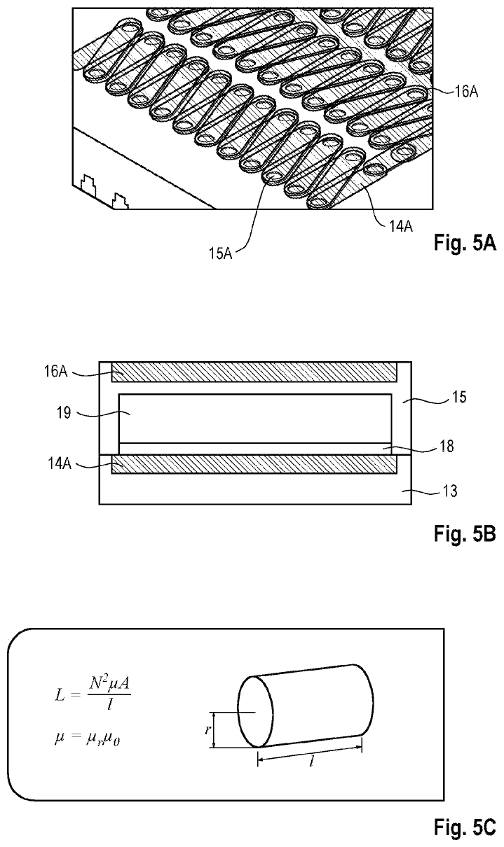

FIG. 4E shows the assembly after depositing a second plateable encapsulation layer 15 onto the upper main face of the first encapsulation layer 13 and the strip-like metallization areas 14A. Before depositing the second plateable encapsulation layer 15, an adhesion layer could be deposited onto the upper main face of the first encapsulation layer 13 and the strip-like metallization areas 14A followed by a layer of a high permeability material in order to increase the inductance of the inductor (see FIG. 5B).

FIG. 4F shows the assembly after activating areas in an upper layer portion of the second plateable encapsulation layer 15 and thereby forming electrically conductive columns 15A which can be essentially vertical and which will serve the purpose of electrical connectors between the lower portions of the windings of the inductor and upper portions to be formed in the next step. The activation can again be done by a laser beam irradiating the second plateable encapsulation layer 15 in a point by point manner such that each one of the thereby generated electrically conductive columns 15A is electrically connected with one of the ends of the strip-like metallization areas 14A.

FIG. 4G shows the assembly after forming a second metallization layer 16 in the form of strip-like slanted metallization areas 16A by electrolytic or electroless plating in such a way that each one of the strip-like metallization areas 16A is electrically connected between upper ends of diagonally neighbored electrically conductive columns 15A. The strip-like metallization areas 16A will turn out to become second upper portions of windings of the inductor to be formed. As can be seen in FIGS. 4G and H, strip-like slanted metallization areas 16A can be arranged in four rows, the rows lying next to each other wherein in each row the strips are arranged in parallel and side-by-side with each other, however with a changing slanted direction from one row to the other. As a result, each slanted strip-like metallization area 16A is connected to one end of a strip-like metallization area 14A and to one end of another end of a different strip-like metallization area 14A via two different vertical columns 15A.

FIG. 4H shows an enlarged section of FIG. 4G in which both the lower strip-like metallization areas 14A and the upper slanted strip-like metallization areas 16A can be seen wherein the latter are electrically connected between upper ends of diagonally neighbored electrically conductive columns 15A. The inductance of such an inductance can be in the order of 3 nH, based on 25 μm trace thickness and 50 μm layer thickness of the second plateable encapsulation layer 15 corresponding to 50 μm length of the electrically conductive columns 15A. The relative permeability of the second plateable encapsulation layer can be in the order of 1.

FIG. 4I shows the assembly after depositing a third plateable encapsulation layer 17 onto the upper main face of the second plateable encapsulation layer 15 and the strip-like metallization areas 16A. It is also possible that the third encapsulation layer 17 is not made of a plateable material.

FIG. 5A corresponds to FIGS. 4G and 4H and shows again the assembly after forming the second metallization layer 16 in the form of the strip-like slanted metallization layers 16A.

FIG. 5B shows a vertical cross-section through the intermediate product. As was indicated above, before depositing the second plateable encapsulation layer 15 a nonconductive adhesive layer 18 can be deposited on the upper surface of the first encapsulation layer 13 and the strip-like metallization areas 14A and thereafter a high permeability material layer 19 can be attached to the adhesive layer 18 in order to increase the inductance of the inductor. In case of a magnetic alloy, e.g. a soft magnetic cobalt-iron alloy a relative permeability in the order of 18.000 with a thickness of layer 19 of 50 μm could be obtained, resulting in inductance of 0.24 mH for 1 layer of fabrication.

Alternatively, instead of depositing the high permeability material layer 19, the second plateable encapsulation layer 15 could be pre-mixed with a magnetic alloy powder or particles to enhance its magnetic properties.

FIG. 5C shows a sketch illustrating the well-known formula for the inductance of an inductor with the following parameters:
L=Inductance of the coil
N=Number of turns in wire coil (straight wire=1)
μ=Permeability of core material
μᵣ=Relative permeability
μ₀₌1.26 ×10⁻⁶ T−m/At permeability of free space
A=Area of coil
L=Average length of coil

According to a further embodiment of the method 100, the passive electrical component is a resistor.

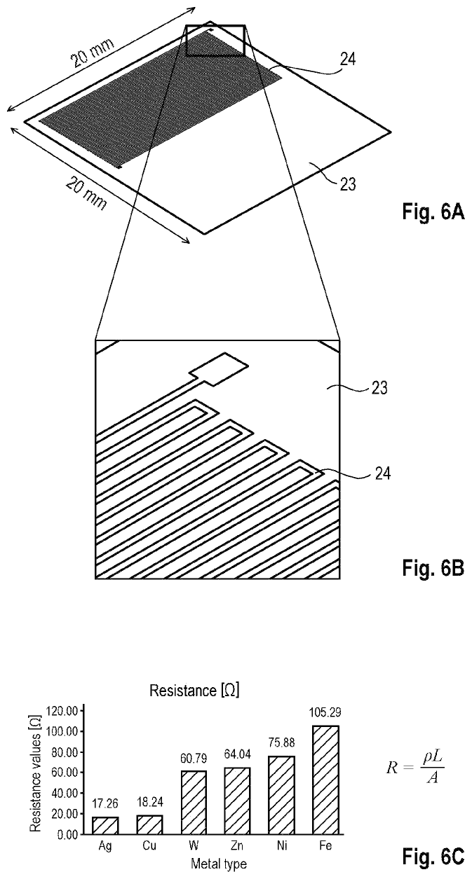

FIG. 6 comprises FIG. 6A to 6C and illustrates the fabrication of an electrical or electronic device in which as a passive component a resistor is manufactured.

FIG. 6A shows a perspective down view on an intermediate product of a process flow. The intermediate product comprises a plateable encapsulation layer 23 which can be disposed on any kind of substrate as was shown in any one of the embodiments. On an upper surface of the plateable encapsulation layer 23 a meander-shaped or wound wire structure 24 is disposed which can be employed as a resistor and may comprise end pads which may be connected to any kind of electrical circuit.

FIG. 6B shows an enlarged section of the wire structure 24. The wire structure 24 can be fabricated by laser activating an area of the plateable encapsulating layer 23 which area corresponds to the dimensions of the wire structure to be fabricated, and thereafter depositing any kind of metal onto the laser activated area by electrolytic or electroless plating.

FIG. 6C shows a diagram showing the achievable resistance values in dependence on the used metal type together with the well-known formula for the resistance of the resistor. The resistance values are related to 50% of the surface used for the wire structure 24. The formula contains the following parameters:
R=Resistance
p=resistivity
A=cross sectional area

According to a further embodiment of the method 100, the passive electrical component is a transformer.

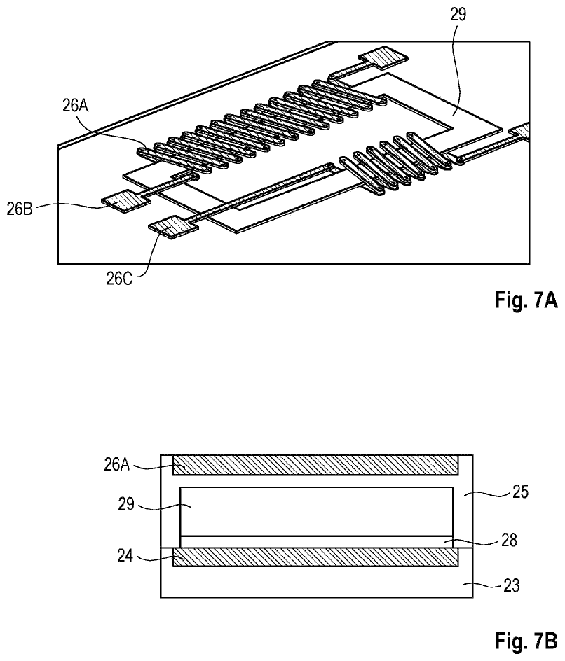

FIG. 7 comprises FIGS. 7A and 7B and shows a perspective view of an electrical or electronic device in which as a passive component a transformer is manufactured (A), and a vertical cross-section through the intermediate product (B)

The transformer as shown in FIG. 7A comprises first and second windings 26A and a closed magnetic core 29 disposed between respective upper and lower portions of the first and second windings 26A, respectively. The first and second windings are connected with outer pads 26B, 26C. The windings can be fabricated in the same way as it was described above in FIG. 4 in connection with the fabrication of the inductor so that the details will not be repeated here.

FIG. 7B shows a vertical cross-section through one of the first or second windings. Accordingly the transformer comprises a first (plateable) encapsulation layer 23, a first metallization layer 24 comprising lower portions of the winding, a second (plateable) encapsulation layer 25, and second metallization layer 26 comprising upper portions of the winding. The magnetic core can be of a high permeability material embedded within the second encapsulation layer 25, and the magnetic core 29 can be attached to the first metallization layer 24 by means of an adhesion layer 28.

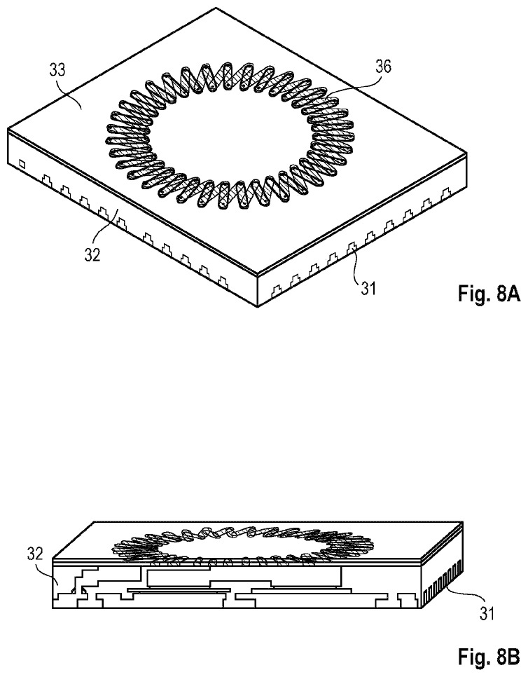

FIG. 8 comprises FIGS. 8A and 8B and shows a perspective view of an electrical or electronic device in which as a passive component an inductor is manufactured (A), and another perspective view of the device also showing the underlying semiconductor device structure.

As shown in FIG. 8 the device may comprise a substrate 31 which can be, for example, a leadframe or any other substrate as was mentioned before. On the substrate 31 a structure 32 is disposed which can be a complete electronic circuit comprising one or more interconnected semiconductor chips as in indicated in FIG. 8B. Above the structure 31 an inductor 36 is fabricated which is electrically connected with the electronic circuit and may serve as output inductor of the electronic circuit. The inductor 36 can be fabricated on the basis of a layer stack 33 as was described in connection with FIG. 4. The inductor 36 can be comprised of a closed ring or of a form as shown in FIG. 4G.

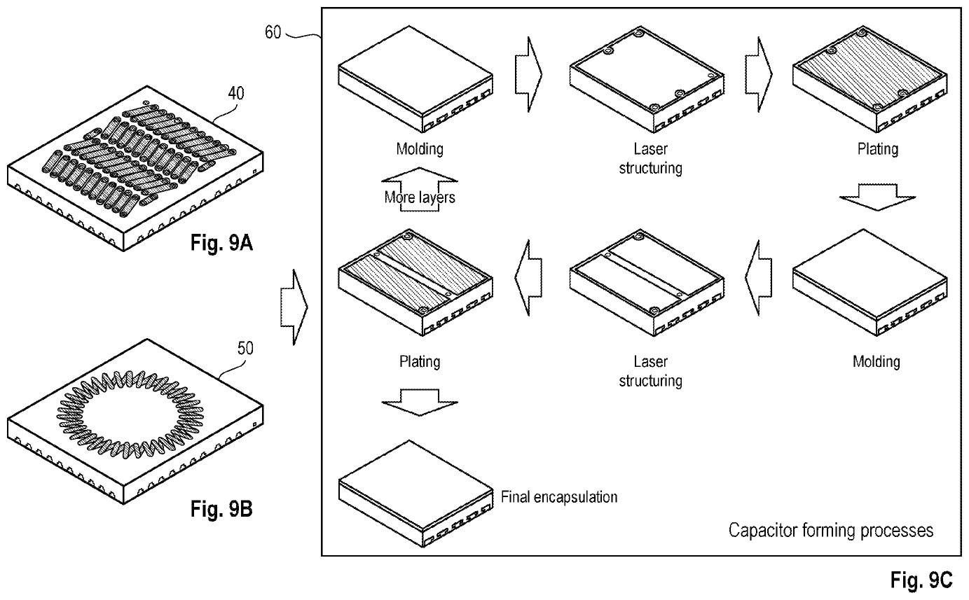

Finally FIG. 9 schematically illustrates a further embodiment in which two different passive components, namely an inductor and a capacitor, are fabricated in one device.

In particular, FIG. 9 comprises FIG. 9A to 9C and illustrates a method of fabricating an inductor as well as a capacitor in one device package. At first a device according to FIG. 9A or 9B is fabricated. FIG. 9A shows a device 40 which may correspond to the device shown in FIG. 4G, and FIG. 9B shows a device 50 which may correspond to the device shown in FIG. 8. Then in a further fabrication process a capacitor is fabricated above the inductor of one of the device 40 or 50. The process is schematically designated with reference 60 and may correspond to the fabrication process as described in FIG. 2. In this way an inductor and a capacitor can be integrated in one device package and they may, for example, serve as output inductor and output capacitor of a semiconductor half-bridge circuit.

### EXAMPLES

In the following, a method for fabricating an electrical module and an electrical module will be explained by means of examples.

Example 1 is a method for fabricating an electrical or electronic device package, the method comprising providing a first plateable encapsulation layer, activating first selective areas on a main surface of the first plateable encapsulation layer, forming a first metallization layer by electrolytic or electroless plating on the first activated selective areas, and fabricating a passive electrical component on the basis of the first metallization layer.

Example 2 is a method according to Example 1, further comprising applying a second plateable encapsulation layer onto the first metallization layer, activating second selective areas on a main surface of the second plateable encapsulating layer, forming a second metallization layer on the second activated selected areas by electrolytic or electroless plating.

Example 3 is a method according to Example 2, further comprising fabricating a passive electrical component on the basis of the first and second metallization layers.

Example 4 is a method according to Example 1, wherein the passive electrical component is a resistor fabricated in the first metallization layer.

Example 5 is a method according to any one of Examples 2 or 3, wherein
the passive electrical component is a capacitor comprising a first capacitor plate fabricated in the first metallization layer and a second capacitor plate fabricated in the second metallization layer.

Example 6 is a method according to Example 5, wherein applying the second plateable encapsulation layer comprises incorporating a dielectric material of a high dielectric constant into the second plateable encapsulation layer.

Example 7 is a method according to any one of examples 2 or 3, wherein the passive electrical component is an inductor or transformer comprising a coil comprising a plurality of coil windings, wherein first portions of the coil windings are fabricated in the first metallization layer, second portions of the coil windings are fabricated in the second metallization layer, and third portions of the coil windings are formed as electrical via connections between the first and the second portions in the second plateable encapsulation layer.

Example 8 is a method according to Example 7, wherein the electrical via connections are fabricated by one or more of laser activated vias, vertical wires, stub bumps, or solder balls.

Example 9 is method according to Example 7 or 8, wherein applying the second plateable encapsulation layer comprises incorporating a material of a high permeability into the second plateable encapsulation layer.

Example 10 is a method according to any one of the preceding Examples, wherein activating selective areas is performed by a laser beam.

Example 11 is an electrical or electronic device package, comprising:
a first plateable encapsulation layer comprising first activated areas on a main surface of the first plateable encapsulation layer;
a first metallization layer disposed on the first activated areas; and
a passive electrical component formed on the basis of the first metallization layer.

Example 12 is the device package according to Example 11, further comprising a second plateable encapsulation layer disposed on the first metallization layer and comprising second activated areas on or in the second plateable encapsulating layer; and a second metallization layer disposed on the second activated areas.

Example 13 is the device package according to Example 10 or 11, further comprising a passive electrical component formed on the basis of the first and second metallization layers.

Example 14 is the device package according to Example 11, wherein the passive electrical component is a resistor fabricated in the first metallization layer.

Example 15 is the device package according to any one of Examples 11 to 13, wherein the passive electrical component is a capacitor comprising a first capacitor plate fabricated in the first metallization layer and at least one second capacitor plate fabricated in the second metallization layer.

Example 16 is the device package according to Example 15, wherein a dielectric material layer of a high dielectric constant is incorporated within the second plateable encapsulation layer.

Example 17 is the device package according to any one of Examples 11 to 13, wherein the passive electrical component is an inductor or transformer comprising a coil comprising a plurality of coil windings, wherein first portions of the coil windings are fabricated in the first metallization layer, second portions of the coil windings are fabricated in the second metallization layer, and third portions of the coil windings are formed as electrical via connections between the first and the second portions in the second plateable encapsulation layer.

Example 18 is the device package according to Example 17, wherein the electrical via connections are fabricated by one or more of laser activated vias, vertical wires, stub bumps, or solder balls.

Example 19 is the device package according to Example 17 or 18, wherein a material layer of a high permeability is incorporated within the second plateable encapsulation layer.

Example 20 is a method for fabricating an electrical or electronic device package, the method comprising
providing a first encapsulation layer;
forming a first metallization layer on the first encapsulation layer by electrolytic or electroless plating;
applying a second encapsulation layer onto the first metallization layer;
forming a second metallization layer on the second encapsulation layer by electrolytic or electroless plating; and
fabricating a passive electrical component on the basis of the first and second metallization layers.

Example 21 is the method according to Example 20, wherein one or more of the first and second encapsulation layers comprise a plateable compound material.

Example 22 is the method according to Example 20 or 21, wherein the passive electrical component is a capacitor comprising a first capacitor plate fabricated in the first metallization layer and at least one second capacitor plate fabricated in the second metallization layer.

Example 23 is the method according to Example 22, wherein applying the second encapsulation layer comprises incorporating a dielectric material layer of a high dielectric constant into the second encapsulation layer.

Example 24 is the method according to any one of Examples 20 or 21, wherein the passive electrical component is an inductor or transformer comprising a coil comprising a plurality of coil windings, wherein first portions of the coil windings are fabricated in the first metallization layer, second portions of the coil windings are fabricated in the second metallization layer, and third portions of the coil windings are formed as electrical via connections between the first and the second portions in the second encapsulation layer.

Example 25 is the method according to Example 24, wherein the electrical via connections are fabricated by one or more of laser activated vias, vertical wires, stub bumps, or solder balls.

Example 26 is the method according to Example 24 or 25, wherein applying the second encapsulation layer comprises incorporating a material layer of a high permeability into the second encapsulation layer.

Example 27 is an electrical or electronic device package comprising a first encapsulation layer, a first metallization layer disposed on the first encapsulation layer, a second encapsulation layer disposed on the first metallization layer, a second metallization layer disposed on the second encapsulation layer; and
a passive electrical device fabricated on the basis of first and second metallization layers.

Example 28is the device package according to Example 27, wherein one or more of the first and second encapsulation layers comprises a plateable compound material.

Example 29 is the device package according to Example 27 or 28, wherein the passive electrical device is a capacitor comprising a first capacitor plate fabricated in the first metallization layer and at least one second capacitor plate fabricated in the second metallization layer.

Example 30 is the device package according to Example 29, wherein a dielectric material layer of a high dielectric constant is incorporated within the second encapsulation layer.

Example 31 is the device package according to Example 27 or 28, wherein the passive electrical device is an inductor or transformer comprising a coil comprising a plurality of coil windings, wherein first portions of the coil windings are fabricated in the first metallization layer, second portions of the coil windings are fabricated in the second metallization layer, and third portions of the coil windings are formed as electrical via connections between the first and the second portions in the second encapsulation layer.

Example 32 is the device package according to Example 31, wherein a material layer of a high permeability is incorporated within the second encapsulation layer.

In addition, while a particular feature or aspect of an embodiment of the disclosure may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Furthermore, it should be understood that embodiments of the disclosure may be implemented in discrete circuits, partially integrated circuits or fully integrated circuits or programming means. Also, the term “exemplary” is merely meant as an example, rather than the best or optimal. It is also to be appreciated that features and/or elements depicted herein are illustrated with particular dimensions relative to one another for purposes of simplicity and ease of understanding, and that actual dimensions may differ substantially from that illustrated herein.

Although specific embodiments have been illustrated and described herein, it will be appreciated by those of ordinary skill in the art that a variety of alternate and/or equivalent implementations may be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

1. A method for fabricating an electrical or electronic device package, the method comprising:
providing a first plateable encapsulation layer;
activating first selective areas on a main surface of the first plateable encapsulation layer;
forming a first metallization layer by electrolytic or electroless plating on the first activated selective areas; and
fabricating a passive electrical component on the basis of the first metallization layer.

2. The method according to claim 1, further comprising:
applying a second plateable encapsulation layer onto the first metallization layer;
activating second selective areas on a main surface of the second plateable encapsulating layer;
forming a second metallization layer on the second activated selected areas by electrolytic or electroless plating.

3. The method according to claim 2, further comprising fabricating a passive electrical component on the basis of the first and second metallization layers.

4. The method according to claim 1, wherein the passive electrical component is a resistor fabricated in the first metallization layer.

5. The method according to claim 2, wherein the passive electrical component is a capacitor comprising a first capacitor plate fabricated in the first metallization layer and a second capacitor plate fabricated in the second metallization layer.

6. The method according to claim 5, wherein applying the second plateable encapsulation layer comprises incorporating a dielectric material of a high dielectric constant into the second plateable encapsulation layer.

7. The method according to claim 2, wherein the passive electrical component is an inductor or transformer comprising a coil comprising a plurality of coil windings, wherein first portions of the coil windings are fabricated in the first metallization layer, second portions of the coil windings are fabricated in the second metallization layer, and third portions of the coil windings are formed as electrical via connections between the first and the second portions in the second plateable encapsulation layer.

8. The method according to claim 7, wherein the electrical via connections are fabricated by one or more of laser activated vias, vertical wires, stub bumps, or solder balls.

9. The method according to claim 7, wherein applying the second plateable encapsulation layer comprises incorporating a material of a high permeability into the second plateable encapsulation layer.

10. The method according to claim 1, wherein activating selective areas is performed by a laser beam.

11. An electrical or electronic device package, comprising: a first plateable encapsulation layer comprising first activated areas on a main surface of the first plateable encapsulation layer; a first metallization layer disposed on the first activated areas; and a passive electrical component formed on the basis of the first metallization layer.

12. The device package according to claim 11, further comprising a second plateable encapsulation layer disposed on the first metallization layer and comprising second activated areas on or in the second plateable encapsulating layer; and a second metallization layer disposed on the second activated areas.

13. The device package according to claim 10, further comprising a passive electrical component formed on the basis of the first and second metallization layers.

14. The device package according to claim 11, wherein the passive electrical component is a resistor fabricated in the first metallization layer.

15. The device package according to claim 11, wherein the passive electrical component is a capacitor comprising a first capacitor plate fabricated in the first metallization layer and at least one second capacitor plate fabricated in the second metallization layer.

16. The device package according to claim 15, wherein a dielectric material layer of a high dielectric constant is incorporated within the second plateable encapsulation layer.

17. The device package according to claim 11, wherein the passive electrical component is an inductor or transformer comprising a coil comprising a plurality of coil windings, wherein first portions of the coil windings are fabricated in the first metallization layer, second portions of the coil windings are fabricated in the second metallization layer, and third portions of the coil windings are formed as electrical via connections between the first and the second portions in the second plateable encapsulation layer.

18. The device package according to claim 17, wherein the electrical via connections are fabricated by one or more of laser activated vias, vertical wires, stub bumps, or solder balls.

19. The device package according to claim 17, wherein a material layer of a high permeability is incorporated within the second plateable encapsulation layer.

20. A method for fabricating an electrical or electronic device package, the method comprising:
providing a first encapsulation layer;
forming a first metallization layer on the first encapsulation layer by electrolytic or electroless plating;
applying a second encapsulation layer onto the first metallization layer;
forming a second metallization layer on the second encapsulation layer by electrolytic or electroless plating; and
fabricating a passive electrical component on the basis of the first and second metallization layers.

21. The method according to claim 20, wherein one or more of the first and second encapsulation layers comprise a plateable compound material.

22. The method according to claim 20, wherein the passive electrical component is a capacitor comprising a first capacitor plate fabricated in the first metallization layer and at least one second capacitor plate fabricated in the second metallization layer.

23. The method according to claim 22, wherein applying the second encapsulation layer comprises incorporating a dielectric material layer of a high dielectric constant into the second encapsulation layer.

24. The method according to claim 20, wherein the passive electrical component is an inductor or transformer comprising a coil comprising a plurality of coil windings, wherein first portions of the coil windings are fabricated in the first metallization layer, second portions of the coil windings are fabricated in the second metallization layer, and third portions of the coil windings are formed as electrical via connections between the first and the second portions in the second encapsulation layer.

25. The method according to claim 24, wherein the electrical via connections are fabricated by one or more of laser activated vias, vertical wires, stub bumps, or solder balls.

26. The method according to claim 24, wherein applying the second encapsulation layer comprises incorporating a material layer of a high permeability into the second encapsulation layer.

27. An electrical or electronic device package comprising
a first encapsulation layer;
a first metallization layer disposed on the first encapsulation layer;
a second encapsulation layer disposed on the first metallization layer;
a second metallization layer disposed on the second encapsulation layer; and
a passive electrical device fabricated on the basis of first and second metallization layers.

28. The device package according to claim 27, wherein one or more of the first and second encapsulation layers comprises a plateable compound material.

29. The device package according to claim 27, wherein the passive electrical device is a capacitor comprising a first capacitor plate fabricated in the first metallization layer and at least one second capacitor plate fabricated in the second metallization layer.

30. The device package according to claim 29, wherein a dielectric material layer of a high dielectric constant is incorporated within the second encapsulation layer.

31. The device package according to claim 27, wherein the passive electrical device is an inductor or transformer comprising a coil comprising a plurality of coil windings, wherein first portions of the coil windings are fabricated in the first metallization layer, second portions of the coil windings are fabricated in the second metallization layer, and third portions of the coil windings are formed as electrical via connections between the first and the second portions in the second encapsulation layer.

32. The device package according to claim 31, wherein a material layer of a high permeability is incorporated within the second encapsulation layer.
